(19) United States
(12) Patent Application Publication
(10) Pub. No.: US 2009/0008688 A1
(43) Pub. Date: Jan. 8, 2009

(54) Unit pixels, image sensors and methods of manufacturing the same

(75) Inventors: Young-Hoon Park, Suwon-si (KR); Sang-Il Jung, Seoul (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/213,534

(22) Filed: Jun. 20, 2008

(30) Foreign Application Priority Data
Jul. 5, 2007 (KR) 10-2007-0067575

(51) Int. Cl. H01L 27/146; H01L 31/18

(52) U.S. Cl. 257/292; 438/59; 257/E27.133

(57) ABSTRACT

Unit pixels, image sensors and methods for fabricating the image sensor are provided. A unit pixel includes: a photodiode for accumulating photocharges; a floating diffusion region for detecting the photocharges accumulated in the photodiode; a reset element for periodically resetting the floating diffusion region; a drive element for amplifying the photocharges accumulated in the floating diffusion region; a selection element for selecting the unit pixel; and a silicide layer formed on top surfaces of the transfer gate. The photocharges are transferred to the floating diffusion region via a transfer gate.

### PRIORITY STATEMENT

This application claims priority under 35 U.S.C. § 119 to Korean Patent Application No. 10-2007-0067575 filed on Jul. 5, 2007, in the Korean Intellectual Property Office, the entire contents of which is incorporated herein by reference.

### BACKGROUND

### Description of the Related Art

Conventional image sensors are semiconductor elements that convert optical images into electric signals. Conventional image sensors may be classified as charge coupled devices (CCD) and complementary metal-oxide semiconductor (CMOS) image sensors.

In a conventional charge coupled device, individual MOS capacitors are arranged at locations adjacent to each other, and charge carriers are transferred and accumulated in the MOS capacitors. In a CMOS image sensor, a MOS transistor corresponding to each pixel is formed using CMOS technology in which a control circuit and a signal-processing circuit are utilized as peripheral circuits. CMOS image sensors also utilize a switching method in which outputs are detected sequentially using the MOS transistors.

In a more particular example, a conventional CMOS image sensor may include an active pixel sensor (APS) array region and a logic region. In the APS array region, each unit pixel includes a transfer gate electrode, a photodiode located at both sides of the transfer gate electrode, and a floating diffusion region. In example operation, the APS region detects light and generates an electric signal, and the logic region (peripheral circuit region) processes the generated electric signal.

More specifically, for example, in the APS array region if light is detected in the photodiodes, electron-hole pairs (EHP) are generated and accumulated. The accumulated electron-hole pairs are transferred to the floating diffusion region via the transfer transistor. As a result, the potential in the floating diffusion region is changed, and the active pixel sensor detects and outputs the change in potential.

However, the external light may be incident on the photodiodes and the upper sides of the transfer gates. In this example, the light incident on the transfer gates may generate electron-hole pairs in a channel below the transfer gates and/or the floating diffusion regions. The electron-hole pairs generated in regions other than the regions where the photodiodes are formed may deteriorate the image quality of the image sensor.

### SUMMARY

Example embodiments relate to image sensors and methods of manufacturing the same, for example, image sensors with improved image quality and methods of manufacturing the same. Image sensors and methods of manufacturing the same may suppress and/or prevent light from being incident on transfer gates.

According to at least one example embodiment, a unit pixel may be formed in a pixel region of a substrate. The unit pixel may include a photodiode for accumulating photocharges, a floating diffusion region for detecting the photocharges accumulated in the photodiode, a transfer gate for transferring the photocharges from the photodiode to the floating diffusion region, and a silicide layer formed on a top surface of only the transfer gate.

According to at least some example embodiments, the unit pixel may further include a reset element for periodically resetting the floating diffusion region, a drive element for amplifying the photocharges accumulated in the floating diffusion region, and a selection element for selecting the unit pixel.

According to at least one other example embodiment, an image sensor may include a substrate having pixel regions and logic regions defined therein. Photodiodes for accumulating photocharges may be formed in the pixel regions, which may further include floating diffusion regions for receiving and detecting the photocharges accumulated in the photodiodes. The pixel regions of the substrate may also include transfer gates for transferring the accumulated photocharges from photodiode to corresponding floating diffusion region. A reset element, a drive element and a selection element may also be formed in each pixel region. The reset elements may periodically reset the floating diffusion regions. The drive elements may amplify the photocharges accumulated in the floating diffusion regions. The selection elements may select the unit pixels. The logic region may include logic elements formed therein. The logic elements may process signals output from the pixel regions. Silicide layers may be formed on top surfaces of the transfer gates and the logic elements.

At least one other example embodiment provides a method of manufacturing a unit pixel in a pixel region of a substrate. According to at least this example embodiment, a photodiode, a floating diffusion region and a transfer gate may be formed in the pixel region of the substrate. A silicide layer may cover the top surface of only the transfer gate.

At least one other example embodiment provides a method of manufacturing an image sensor. According to at least this example embodiment, a substrate having defined pixel regions and logic regions may be prepared, and transfer gates may be formed in the pixel regions of the substrate. Gates of logic elements may be formed in the logic regions of the substrate, and photodiodes may be formed at one side of the transfer gates. Floating diffusion regions may be formed at the other side of the transfer gates, and impurity regions may be formed at both sides of the gates of the logic elements of the logic regions of the substrate. Silicide layers may be formed on top surfaces of the transfer gates in the pixel regions and top surfaces of the gates of the logic elements and the impurity regions in the logic regions.

### BRIEF DESCRIPTION OF THE DRAWINGS

The present invention will become apparent by describing in detail example embodiments thereof with reference to the attached drawings in which:

FIG. 1 is a block diagram illustrating an image sensor according to an example embodiment;

FIG. 2 is a schematic circuit diagram illustrating an active pixel sensor (APS) array of an image sensor according to an example embodiment;

FIG. 3 is a circuit diagram illustrating a unit pixel of an image sensor according to an example embodiment;

FIG. 4 is a schematic plan view illustrating an image sensor according to an example embodiment;

FIG. 5 is a cross-sectional view taken along the line V-V shown in FIG. 4; and

FIGS. 6 to 14 are cross-sectional views sequentially illustrating processes of a method of manufacturing an image sensor according to an example embodiment.

### DETAILED DESCRIPTION OF THE EXAMPLE EMBODIMENTS

Various example embodiments of the present invention will now be described more fully with reference to the accompanying drawings in which some example embodiments of the invention are shown. In the drawings, the thicknesses of layers and regions are exaggerated for clarity.

Detailed illustrative embodiments of the present invention are disclosed herein. However, specific structural and functional details disclosed herein are merely representative for purposes of describing example embodiments of the present invention. This invention may, however, may be embodied in many alternate forms and should not be construed as limited to only the embodiments set forth herein.

Accordingly, while example embodiments of the invention are capable of various modifications and alternative forms, embodiments thereof are shown by way of example in the drawings and will herein be described in detail. It should be understood, however, that there is no intent to limit example embodiments of the invention to the particular forms disclosed, but on the contrary, example embodiments of the invention are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the present invention. As used herein, the term “and/or,” includes any and all combinations of one or more of the associated listed items.

It will be understood that when an element is referred to as being “connected,” or “coupled,” to another element, it can be directly connected or coupled to the other element or intervening elements may be present. In contrast, when an element is referred to as being “directly connected,” or “directly coupled,” to another element, there are no intervening elements present. Other words used to describe the relationship between elements should be interpreted in a like fashion (e.g., “between,” versus “directly between,” “adjacent,” versus “directly adjacent,” etc.).

The terminology used herein is for the purpose of describing particular embodiments only and is not intended to be limiting of example embodiments of the invention. As used herein, the singular forms “a,” “an,” and “the,” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Also, example embodiments of the invention will be described by referring to ideal figures of the present invention, sectional views and/or simplified diagrams. And the shape of the figures may be changed due to manufacturing technologies and/or allowable errors. For example, etch regions illustrated as having right angles may have a round shape or a curved shape. Therefore, regions shown in the figures are illustrated in schematic forms, and the shapes of the illustrated regions in the figures are presented simply by way of illustration and not as a limitation.

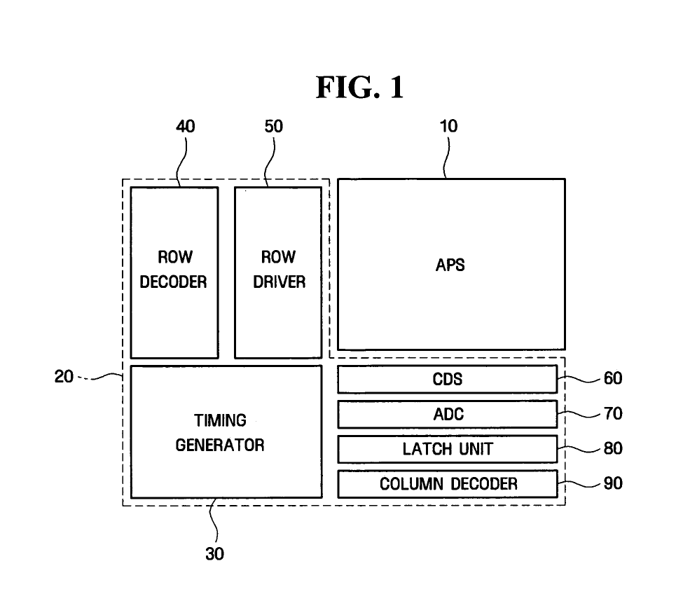

Example embodiments will be described hereinafter with reference to block diagrams or flowchart illustrations of a CMOS image sensor according to an example embodiment thereof. A structure of a CMOS image sensor according to an example embodiment will be described in detail with reference to FIGS. 1 to 5.

FIG. 1 is a schematic block diagram illustrating an image sensor according to an example embodiment.

Referring to FIG. 1, an image sensor may include an active pixel sensor (APS) array region 10 (hereinafter, simply referred to as an APS array region) and a logic region 20 for operating the APS array region 10. In this example, in the APS array region 10, pixels including light-receiving elements may be disposed two-dimensionally.

As noted above, the APS array region 10 may include a plurality of pixels disposed two-dimensionally, and may convert an optical signal into an electric signal. In one example, the APS array region 10 may be driven by a plurality of driving signals including, for example, a pixel-selection signal SEL, a reset signal RX, a charge-transfer signal TX, and the like, from a row driver 50. The converted signal (e.g., optical to electrical signal) may be output to a correlated double sampler (CDS) 60 through a vertical signal line.

The logic region 20 may include a timing generator 30, a row decoder 40, a row driver 50, a correlated double sampler 60, an analog-to-digital converter (ADC) 70, a latch unit 80, a column decoder 90, and the like.

The timing generator 30 may apply a timing signal and a control signal to the row decoder 40 and the column decoder 90. The row driver 50 may apply a plurality of driving signals to drive a plurality of unit pixels in the APS array region 10 according to the result decoded by the row decoder 40. In one example, when unit pixels are arranged in a matrix, a driving signal may be applied for each row of the matrix.

The correlated double sampler 60 may receive, hold and sample an electric signal generated by the APS array region 10. In one example, the correlated double sampler 60 may perform double sampling of a specific noise and a signal level of the generated electric signal, and output a difference between the noise level and the signal level.

The analog-to-digital converter 70 may convert an analog signal corresponding to the difference level output from the correlated double sampler 60 into a digital signal, and output the digital signal to the latch unit 80.

The latch unit 80 may latch the digital signal, and the latched signal may be sequentially output to an image-signal-processing unit (not shown) according to the result decoded by the column decoder 90.

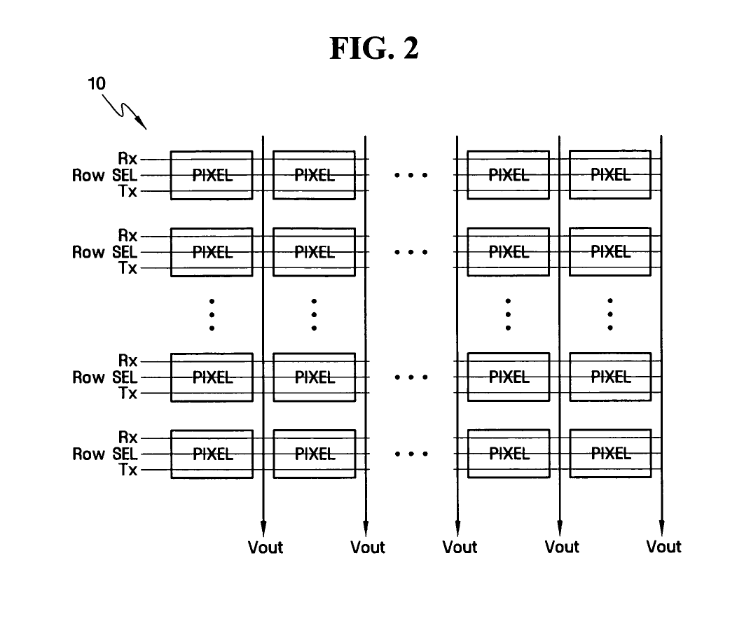

FIG. 2 is a schematic circuit diagram illustrating an active pixel sensor (APS) array of an image sensor according to an example embodiment.

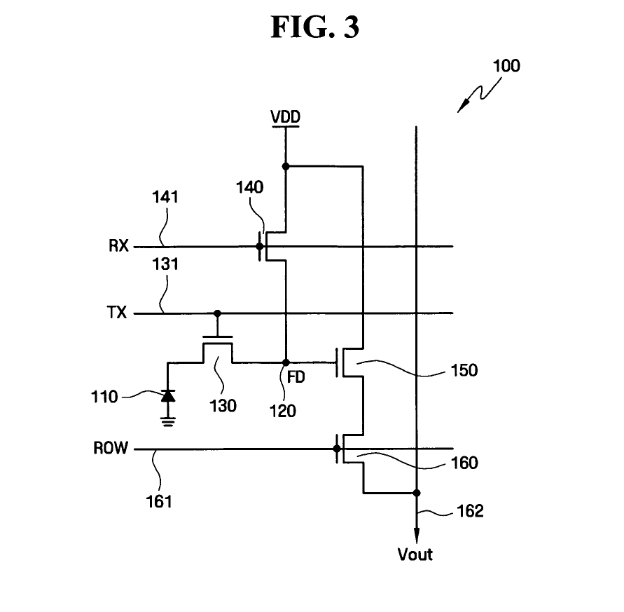

Referring to FIG. 2, the APS array region 10 of the image sensor, which may convert the optical signal into the electric signal, may have a structure in which unit pixels 100 are arranged in a matrix. Each of the unit pixels may have a structure shown in the equivalent circuit diagram of FIG. 3.

FIG. 3 is a circuit diagram illustrating a unit pixel of an image sensor according to an example embodiment.

Referring to FIG. 3, each unit pixel region 100 may have a structure including a plurality of (e.g., four) transistors 130, 140, 150 and 160, a light-receiving element 110 and read elements. Although FIG. 3 only shows four transistors, example embodiments are not limited thereto. For example, each unit pixel region 100 may include three transistors, five transistors, or a photogate structure similar or substantially similar to a structure including four transistors.

Referring still to FIG. 3, the light-receiving element 110 may receive light, generate and accumulate photocharges. Read elements may read optical signals incident on the light-receiving element. In this example, the read elements may include a reset element 140, a drive element 150, a selection element 160, and the like.

In a more specific example, the light-receiving element 110 may generate charges corresponding to incident light and accumulate the generated charges. The light-receiving element 110 may be a photodiode, a phototransistor, a photogate, a pinned photodiode (PPD), a combination thereof or the like. The light-receiving element 110 may be connected to a charge-transfer element 130 that transfers the accumulated photocharge to the floating diffusion (FD) region 120.

The floating diffusion region 120 may receive the accumulated charge from the light-receiving element 110. Because the floating diffusion region 120 has a parasitic capacitance, the charges may be accumulated in the floating diffusion region 120. Further, if the floating diffusion region 120 is electrically connected to the drive element 150, the floating diffusion region 120 may control the drive element 150.

The charge-transfer element 130 may transfer the charges from the light-receiving element 110 to the floating diffusion region 120. In one example, the charge-transfer element 130 may include a transistor or transistor circuit, and may be controlled by a charge-transfer signal TX.

The reset element 140 may periodically reset the floating diffusion region 120. A source of the reset element 140 may be connected to the floating diffusion region 120 and a drain thereof may be connected to a voltage source VDD. In addition, the reset element 140 may be driven by a voltage bias supplied through a reset line 141. Accordingly, when the reset element 140 is turned on by the bias supplied through the reset line 141, a voltage from the voltage source VDD, which is connected to the drain of the reset element 140, may be applied to the floating diffusion region 120.

The drive element 150 may function as a source-follower buffer amplifier together with a constant current source (not shown) located outside the unit pixel region 100. The drive element 150 may amplify the change in the potential of the floating diffusion region 120 that receives the photocharges accumulated in the light-receiving element 110, and may output the potential to an output line 162.

The selection element 160 may select unit pixels to be read in a row unit. The selection element 160 may be driven by a bias supplied from a row selection line ROW. When the selection element is turned on, the voltage from the voltage source connected to the drain of the selection element 160 may be supplied to the drain of the drive element 150.

Further, drive signal lines 131, 141, and 161 of the charge-transfer element 130, the reset element 140, and the selection element 160, respectively, may extend in a row direction (horizontal direction) such that unit pixels included in the same row may be driven simultaneously or concurrently.

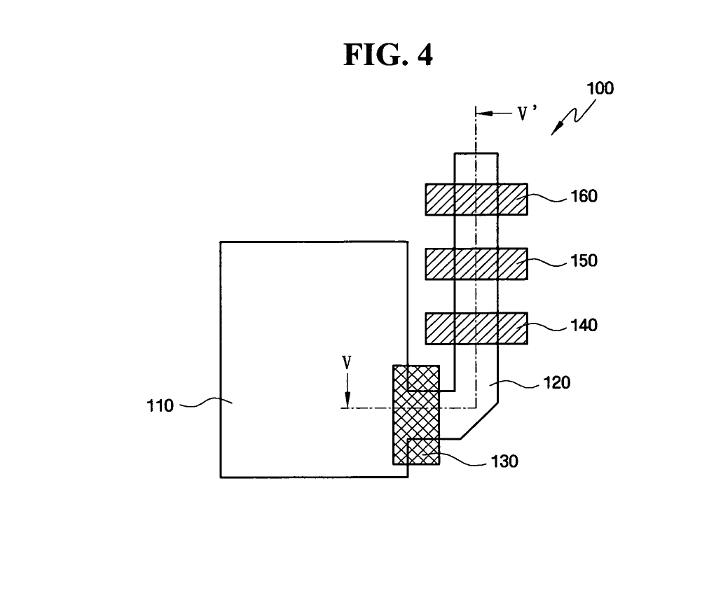

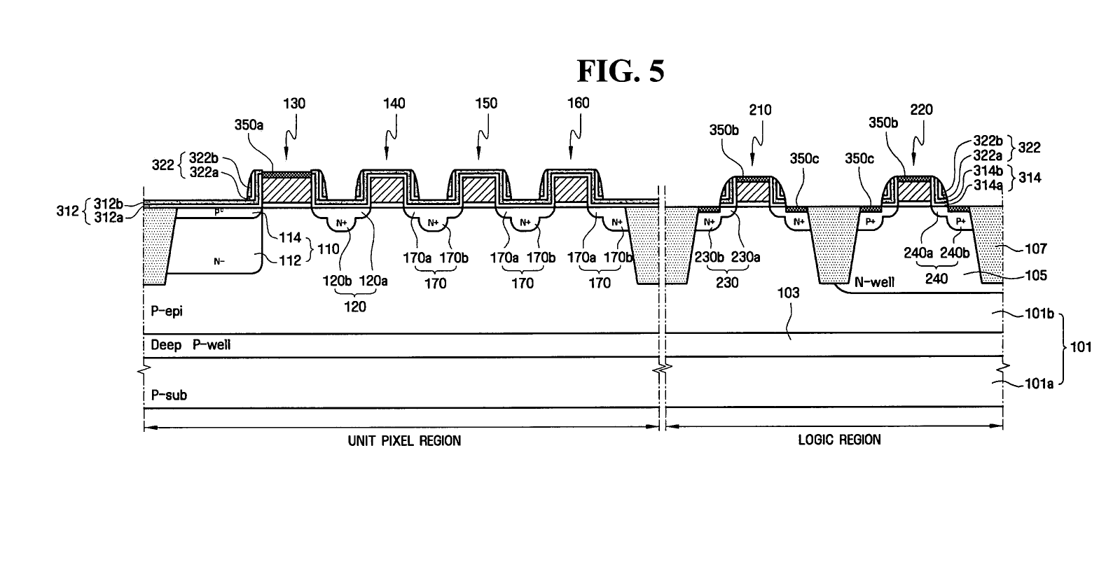

FIG. 4 is a schematic plan view illustrating a unit pixel of an image sensor according to an example embodiment. FIG. 5 is a cross-sectional view taken along the line V-V of FIG. 4.

Referring to FIGS. 4 and 5, because the unit pixel regions 100 are arranged in a matrix in the APS array region (e.g., APS array region 10 in FIGS. 1 and 2), a substrate 101 may be divided into unit pixel regions 100 formed in a rectangular shape. The light-receiving element 110 may be located at the center of each unit pixel region 100. In each unit pixel region 100, the floating diffusion region 120, the charge-transfer element 130, the reset element 140, the drive element 150, and the selection element 160 may be located around the light-receiving element 110.

Logic elements, for example, transistors (e.g., NMOS and PMOS transistors) 210 and 220, a capacitor, and a resistor may be located in the logic region to form a logic circuit.

Referring to FIG. 5, an image sensor according to an example embodiment may use a substrate 101 in which a p-type epitaxial layer 101b is formed on a p-type bulk substrate 101a. In addition, a deep p-well 103 (serving as a p-type impurity region) may be formed in the substrate 101. The deep p-well 103 may be separate and apart from the surface of the substrate 101 and may be formed in the p-type epitaxial layer 101b.

The deep p-well 103 may form a potential barrier to suppress and/or prevent charges generated in a portion (e.g., deep portion) of the bulk substrate 101a from flowing through the light-receiving element 110. Further, the deep p-well 103 may form a crosstalk barrier that reduces crosstalk between pixels due to random drift of the charges by increasing recombination between the electrons and the holes.

The deep p-well 103 may be formed such that it has a higher (e.g., highest) concentration in the depth of about 3 μm to about 12 μm, inclusive, from the surface of the substrate 101 and may have a layer thickness of about 1 μm to about 5 μm, inclusive. In this example, the dimension that corresponds to the depth of about 3 μm to about 12 μm may be the same or substantially the same as the absorption wavelength of red or near infrared region light in silicon. When the depth of the deep p-well 103 from the surface of the substrate 101 is relatively shallow, a diffusion suppression effect may improve, and crosstalk may be reduced. However, if the depth of a region of the light-receiving element is relatively shallow, sensitivity with respect to incident light that has a relatively long wavelength (e.g., red wavelength), whose photoelectric conversion ratio is relatively large at a deep portion, may decrease. Accordingly, a location in which the deep p-well 103 is formed may be adjusted according to a wavelength region of the incident light.

In this example embodiment, the p-type epitaxial layer 101b may be grown on the p-type bulk substrate 101a, and the deep p-well 103 may be formed in the p-type epitaxial layer 101b. Example embodiments, however, are not limited thereto. For example, instead of the p-type bulk substrate 101a, an n-type bulk substrate may be used, and instead of the p-type epitaxial layer 101b, an n-type epitaxial layer may be used. In some cases, the deep p-well 103 may be omitted (e.g., may not be formed). More generally, the substrate 101 may have various combinations.

A device isolation layer 107 may be formed in the substrate to discriminate between an active region and a field region. In the substrate 101 of the logic region, an n-well 105 may be formed to form a transistor (e.g., a PMOS transistor).

A plurality of gates may be formed on the substrate 101. For example, the transfer gate 130, the reset gate 140, the drive gate 150, and the selection gate 160 may be disposed on the substrate 101 in a unit pixel region. The gates 210 and 220 of the NMOS and PMOS transistors may be disposed on the substrate 101 in the logic region.

In the unit pixel region, the light-receiving element 110 may be located at one side of the transfer gate 130. In this example embodiment, a pinned photodiode may be formed as the light-receiving element 110. The pinned photodiode 110 may include an n-type photodiode 112 and a p-type photodiode 114 formed by performing ion injection twice. The n-type photodiode 112 may be formed relatively deep in the p-type epitaxial layer 101b, and the p-type photodiode 114 may be formed relatively shallowly on the surface of the n-type photodiode 112. Accordingly, the pinned photodiode 110 may have a PNP conjunction structure in which the p-type epitaxial layer 101b, the n-type photodiode 112, and the p-type photodiode 114 may be laminated.

In this example, the n-type photodiode 112 may absorb incident light and accumulate photocharges. The p-type photodiode 114 may reduce thermally generated electron-hole pairs (EHP) and suppress and/or prevent generation of dark currents. Dark currents may be generated by dangling bonding of silicon, or when a surface of the substrate 101 damages due to etching stress or the like. Accordingly, among the electron-hole pairs that are thermally generated on the surface of the substrate 101, the holes may diffuse to the substrate 101 connected to a ground through the p-type photodiode 114. While the electrons diffuse to the p-type photodiode 114, the electrons may be recombined to the holes and disappear.

In addition, a floating diffusion region 120 formed by injecting n-type impurities may be located at the other side of the transfer gate 130 in the unit pixel region. The floating diffusion region 120 may receive the photocharges accumulated in the pinned photodiode 110 through the transfer gate 130. The floating diffusion region 120 may include relatively low and relatively high doped impurity regions 120a and 120b. According to example embodiments, the floating diffusion region 120 may have a lightly doped drain (LDD) structure or a double doped drain (DDD) structure.

As such, the transfer gate 130 may be disposed on the substrate 101 between the pinned photodiode 110 and the floating diffusion region 120 that are separate and apart from each other. The transfer gate 130 may transfer the photocharges accumulated in the pinned photodiode 110 to the floating diffusion region 120.

Further, in a portion of the substrate 101 that is apart from the transfer gate 130 but adjacent to the floating diffusion region 120, the reset gate 140, the drive gate 150 and the selection gate 160 may be arranged in a separated state. An impurity region 170 having an LDD or DDD structure may be located at one side of each of the reset gate 140, the drive gate 150 and the selection gate 160.

In the unit pixel region, an insulating-layer pattern 312 may be formed to cover the pinned photodiode 110, the floating diffusion region 120, the reset gate 140, the drive gate 150, the selection gate 160, and the impurity regions 170. On the unit pixel region, for example, the insulating-layer pattern 312 may be formed to cover the top surfaces of the structures, except for the top surface of the transfer gate 130.

In this example, the insulating-layer pattern 312 may include a layer (e.g., single layer) of a silicon nitride 312b formed on an oxide layer 312a. The insulating-layer pattern 312 may suppress and/or prevent characteristics of elements located in a unit pixel region from deteriorating during a silicidation process. In one example, the insulating-layer pattern 312 may reduce incident light sensitivity of the pinned photodiode 110. In addition, the insulating-layer pattern 312 may suppress and/or prevent a leakage current in the floating diffusion region 120 from increasing.

Still referring to FIG. 5, spacers 322 may be formed on both sides of the transfer gate 130, the reset gate 140, the drive gate 150 and the selection gate 160 in the unit pixel region. Each of the spacers 322 may include a (e.g., single) nitride layer, or may have a multi-layer structure including, for example, an oxide layer 322a and a nitride layer 322b, as shown in FIG. 5. The insulating-layer pattern 312 may be interposed between the reset gate 140 and its corresponding spacer 322, the drive gate 150 and its corresponding spacer 322 and the selection gate 160 and its corresponding spacer 322. Alternatively, the spacers 322 may be located at both sides of the reset gate 140, the drive gate 150 and the selection gate 160, and the insulating-layer pattern 312 may be formed on the spacers 322.

A silicide layer 350a may be formed on a top surface of the transfer gate 130 exposed to the outside by the insulating-layer pattern 312. The silicide layer 350a formed on the top surface of the transfer gate 130 may have relatively low light transmission characteristics as compared with the gates comprised of polysilicon. Accordingly, when light is incident on an image sensor, the amount of light incident on the transfer gate 130 may be reduced. The electron-hole pairs may be generated in a channel region and/or the floating diffusion region 120 below the transfer gate 130 to suppress and/or prevent deterioration of image quality of the image sensor. For example, the silicide layer 350a may only be formed on the top surface of the transfer gate 130 in the unit pixel region because the sensitivity of elements in the unit pixel region other than the transfer gate 130 is not lowered. As a result, electrical characteristics of the image sensor may be maintained.

The CMOS transistor may be formed on the substrate 101 in the logic region. For example, the gate 210 of the NMOS transistor and the gate 220 of the PMOS transistor may be located on the substrate 101. The impurity regions 230 and 240 having, for example, an LDD structure may be located in the substrate 101 at both sides of the gates 210 and 220.

In addition, first and second spacers 314 and 322 may be formed at respective sides of the gates 210 and 220. For example, the first spacer 314 having an L-shape may be located at both sides of the gates 210 and 220, and the second spacer 322 having a horn shape may be disposed on the first spacer 314. In this example, the first spacer 314 may be formed on the same layer as the insulating-layer pattern 312, and may have a structure in which the oxide layer spacer 314a and the nitride layer spacer 314b are laminated. Further, the second spacer 322 may have a laminated structure including an oxide layer and a nitride layer such that the second spacer 322 is different from the first spacer 314.

On the top surfaces of the gates 210 and 220 and the impurity regions 230 and 240 in the logic region, silicide layers 350b and 350c may be formed to reduce contact resistance. In this case, the silicide layers 350b and 350c located in the logic region may be comprised of the same or substantially the same metal component as the silicide layer 350a disposed on the top surface of the transfer gate 130 in the pixel region.

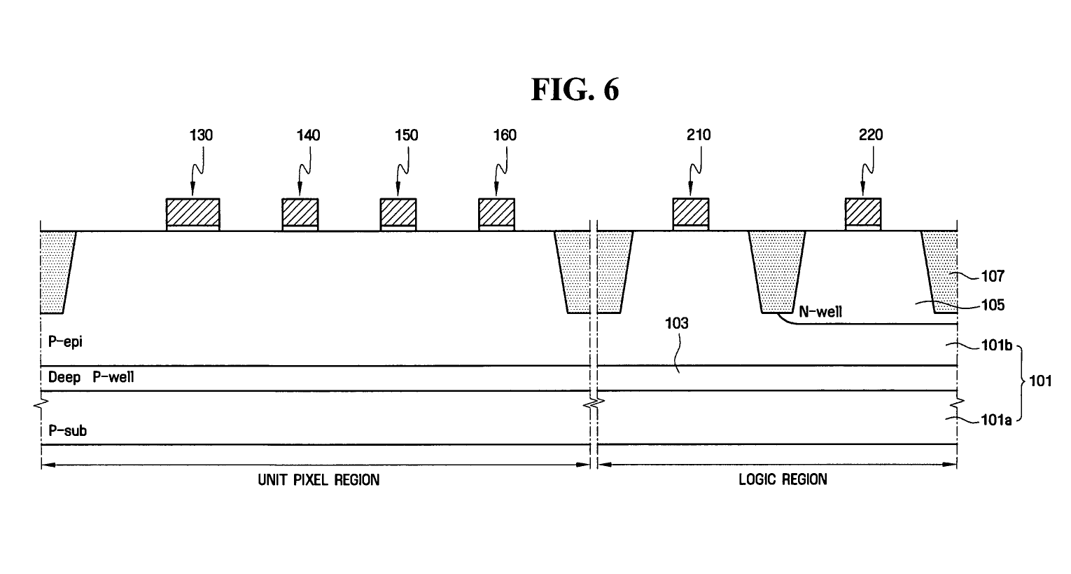

A method of manufacturing an image sensor according to an example embodiment will be described in detail with reference to FIGS. 6 to 14. FIGS. 6 to 14 are cross-sectional views sequentially illustrating processes of a method of manufacturing an image sensor according to an example embodiment.

Referring to FIG. 6, the substrate 101 in which a unit pixel region and a logic region may be discriminated from each other may be prepared. In the substrate 101, the p-type epitaxial layer 101b may be formed on the p-type bulk substrate 101a.

P-type impurities may be injected into the p-type epitaxial layer 101b to form a deep p-well 103. The deep p-well 103 may be formed such that it has a relatively high (e.g., highest) concentration at a depth of about 3 μm to about 12 μm, inclusive, from the surface of the substrate 101 and a layer thickness of about 1 μm to about 5 μm, inclusive.

Still referring to FIG. 6, an n-well 105 may be formed by injecting n-type impurities into a given region of the logic region in the substrate 101. For example, the n-type impurities may be injected into a region in which the PMOS transistor is to be formed.

A device isolation layer 107 may be formed using a Local Oxidation of Silicon (LOCOS) process, a Shallow Trench Isolation (STI) process or the like. The device isolation layer 107 may discriminate between or separate a field region and an active region.

The gate insulating layer and the gate conductive layer may be sequentially laminated on the substrate 101. The gate insulating layer may be comprised of, for example, SiO₂, SiON, SiN, Al₂O₃, Si₃N₄, GeₓO_{y}N_{z}, GeₓSi_{y}O_{z}, other high dielectric materials, combinations thereof or the like. In this example, the high dielectric materials may be formed by an atomic layer deposition (ALD) or similar method using, for example, HfO₂, ZrO₂, Al₂O₃, Ta₂O₅, hafnium silicate, zirconium silicate, a combination thereof or the like. Further, the gate insulating layer may be configured by laminating two or more materials selected from the materials of the exemplified layers as a plurality of layers. The gate conductive layer may be formed by depositing a polysilicon or other similar layer.

The laminated gate insulating layer and the laminated gate conductive layer may be patterned to form the plurality of gates 130, 140, 150, 160, 210 and 220 on the substrate 101. For example, the transfer gate 130, the reset gate 140, the drive gate 150, and the selection gate 160 may be formed on the substrate 101 in the unit pixel region. The gates 210 and 220 of the transistors (e.g., NMOS and PMOS transistors) may be formed on the substrate in the logic region.

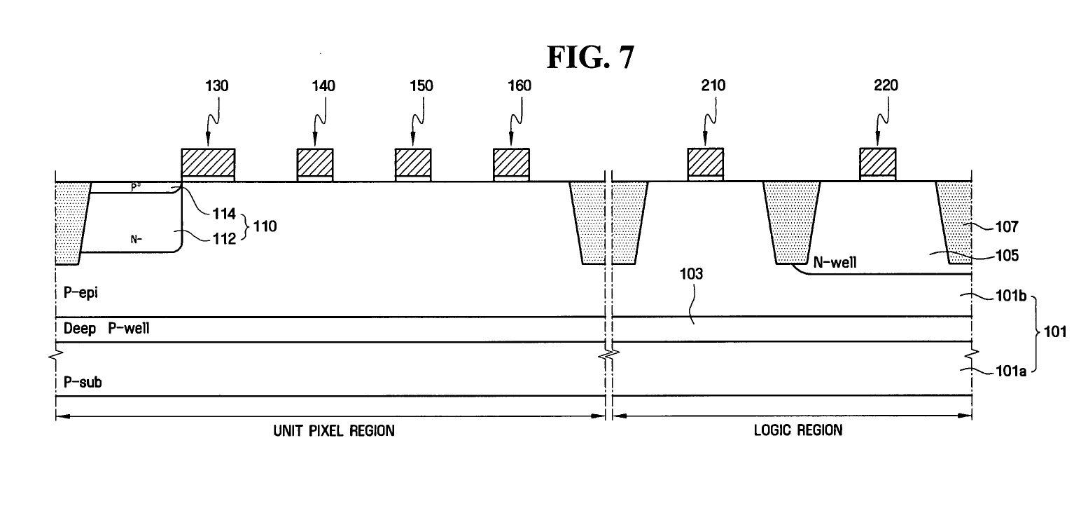

As shown in FIG. 7, the light-receiving element 110 may be formed in the substrate 101 at one side of the transfer gate 130. In this example, the light-receiving element 110 may be formed of a pinned photodiode. A first mask pattern (not shown), exposing a region in which the pinned photodiode is to be formed, may be formed on the substrate 101. The n-type impurities may be injected into the substrate 101 using the first mask pattern, to form the n-type photodiode 112. When forming the n-type photodiode 112, the impurities may be injected at a tilted angle of about 0 to about 15°, inclusive, in a direction along the transfer gate 130. Therefore, the n-type photodiode 112 may partially overlap the transfer gate 130.

After forming the n-type photodiode 112, p-type impurities may be injected using, for example, the first mask pattern used when forming the n-type photodiode 112, to form the p-type photodiode 114 that is relatively lowly doped on the n-type photodiode 112. When the p-type photodiode 114 is formed, the p-type impurities may be injected at a tilted angle of greater than or equal to about 0° in a direction along the device isolation layer 107. The p-type photodiode 114 formed in the above-described method may reduce the electron-hole pairs, which may be thermally generated on the surface of the p-typed epitaxial layer 101b. The p-type photodiode 114 formed in the above-described method may also suppress and/or prevent generation of dark currents.

After forming the pinned photodiode 110, the first mask pattern used when forming the pinned photodiode 110 may be removed. In the above-discussed example embodiments, the pinned photodiode 110 may be formed after forming the plurality of gates 130, 140, 150, 160, 210, and 220, but example embodiments are not limited thereto.

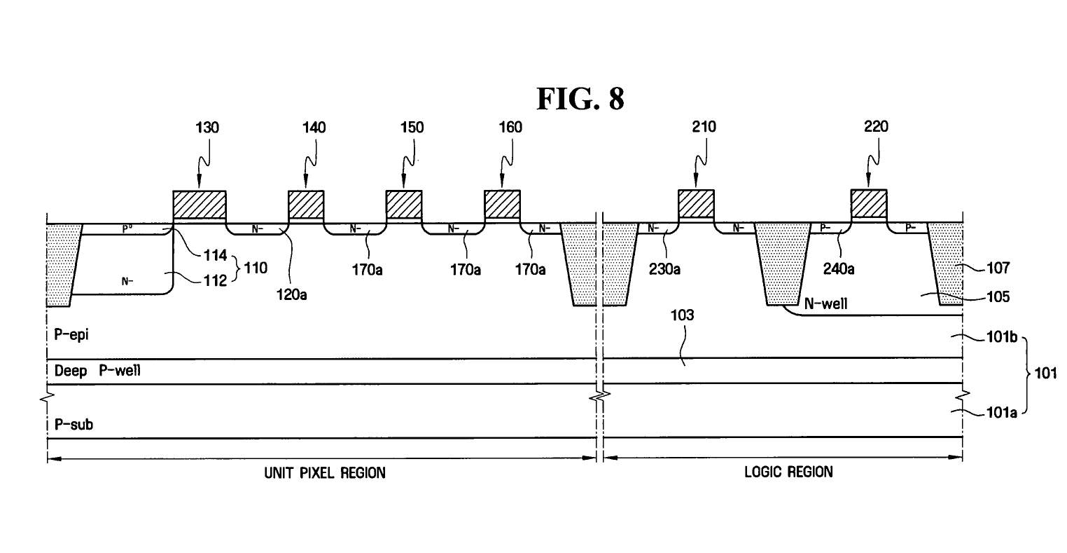

Referring to FIG. 8, a second mask pattern may be formed to cover the pinned photodiode 110, and relatively lowly doped impurity regions 120a, 170a, 230a, and 240a may be formed in the substrate 101 at both sides of the plurality of gates. The relatively lowly doped impurity regions 120a and 170a in the unit pixel region may be formed by doping the same impurity as the n-type photodiode 112. The impurity region 120a formed between the transfer gate 130 and the reset gate 140 may correspond to a relatively lowly doped floating diffusion region.

In the logic region, n-type impurities may be doped at both sides of the gate 210 of the NMOS transistor and p-type impurities may be doped at both sides of the gate 220 of the PMOS transistor to form the relatively lowly doped impurity regions 230a and 240a, respectively. In this example, another mask pattern may be used to form the p-type impurity region.

As such, after forming the relatively lowly doped impurity regions 120a, 170a, 230a, and 240a, the second mask pattern may be removed.

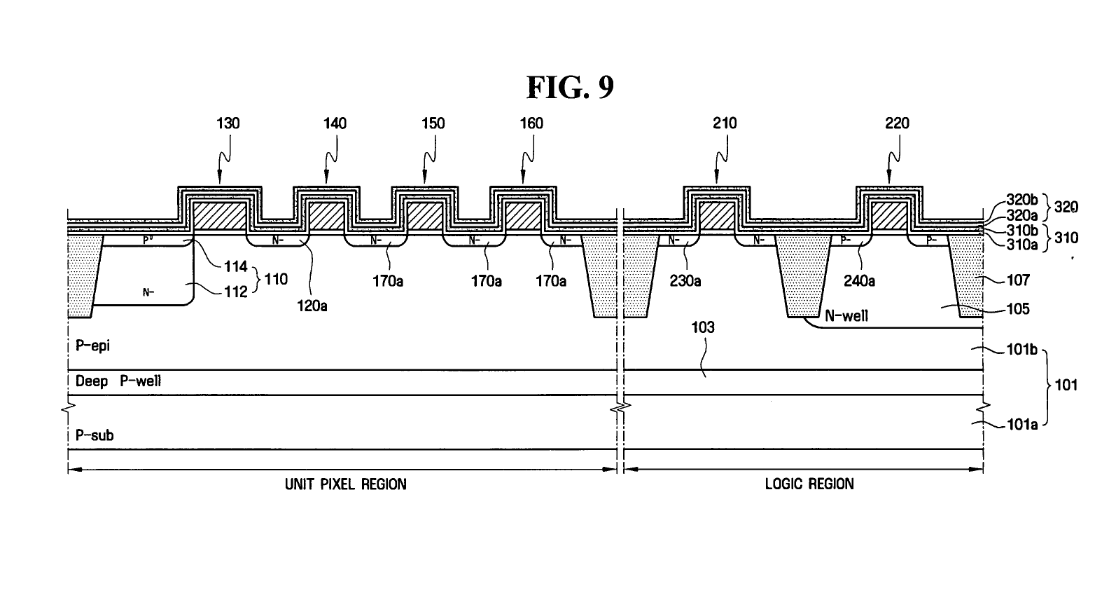

Turning to FIG. 9, as shown over a substantial portion of the (e.g., the entire) surface of the substrate 101 where the gates 130, 140, 150, 160, 210, and 220 are formed, an insulating layer may be formed along surface.

For example, the first and second insulating layers 310 and 320 may be sequentially formed on the substrate 101 where the plurality of gates 130, 140, 150, 160, 210, and 220 are formed. The first insulating layer 310 may be used as a suppression or blocking layer that may suppress and/or prevent damage to the pinned photodiode 110 during subsequent processes and/or may suppress and/or prevent elements in a unit pixel region from being affected by metal materials. The second insulating layer 320 may be used as a spacer-insulating layer to form spacers.

In this example, the first insulating layer 310 may be formed by depositing the silicon nitride layer 310b. An oxide layer 310a may be formed before forming the nitride layer 310b. The oxide layer 310a may be formed through a thermal oxidation process. The oxide layer 310a formed through the thermal oxidation process may improve reliability of a gate insulating layer below the gates and/or restore damage of elements due to etching when the gates are formed, thereby improving electrical reliability.

The second insulating layer 320 may be formed by sequentially depositing the oxide layer 320a and the nitride layer 320b on the first insulating layer 310.

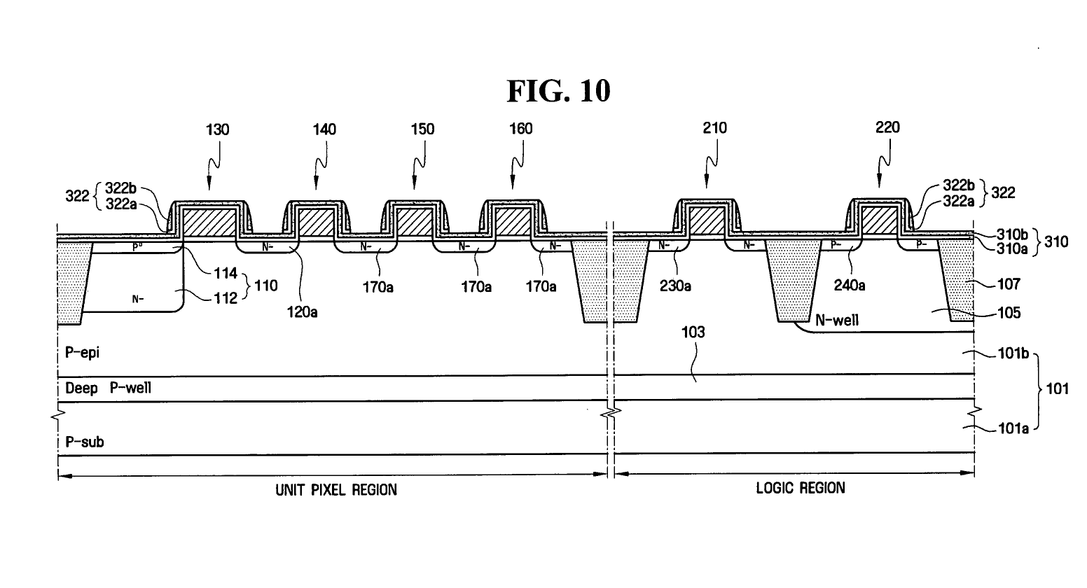

Referring to FIG. 10, the spacers 322 may be formed at both sides of the plurality of gates 130, 140, 150, 160, 210 and 220 using an anisotropic etching process on the second insulating layer 320. When forming the spacer 322, the second insulating layer 320 may include the oxide layer 320a and the nitride layer 320b, and thus, the nitride layer 310a of the first insulating layer 310 may function as an etch stop layer (or etching stopper) during the anisotropic etching process. Each of the spacers 322 formed in the above-described method may include an L-shaped spacer 322a and a spacer 322b. The L-shaped spacer 322a may be comprised of, for example, an oxide layer. The spacer 322b may have a horn shape and may be formed of, for example, a nitride layer.

After forming the spacers 322, the first insulating layer 310 formed on the top surfaces of the gates 130, 140, 150, 160, 210, 220 and the substrate 101 may be exposed.

Although the method of forming the spacers 322 using the second insulating layer 320 has been described with reference to FIGS. 9 and 10, the spacers may be formed at both sides of the gates 130, 140, 150, 160, 210 and 220 using the first insulating layer 310. After forming the spacers, the second insulating layer 320 may be deposited along the surfaces of the resultants. In this example, the second insulating layer 320 formed on the spacers may function as a suppression or blocking layer.

The insulating layer formed along the substrate 101 and the gates 130, 140, 150, 160, 210 and 220 may be located on or below the spacers.

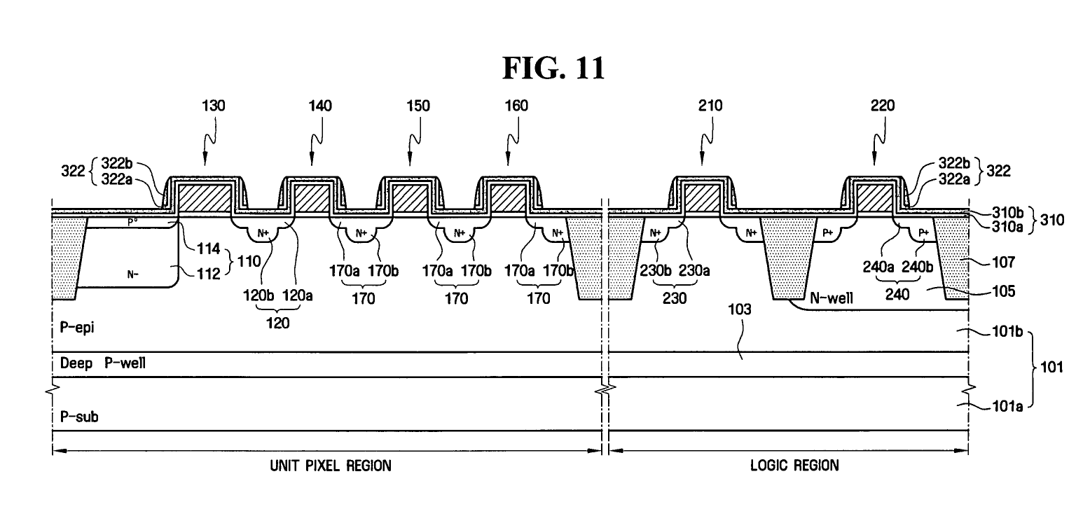

Referring to FIG. 11, the relatively highly doped impurity regions 120b, 170b, 230b and 240b may be formed in the substrate 101 by using the gates 130, 140, 150, 160, 210 and 220 and the spacers 322 formed at both sides of the gates as an ion injection mask. The n-type impurities may be injected in the unit pixel region and the NMOS transistor region of the logic region to form the n-type relatively highly doped impurity regions 120b, 170b and 230b. The p-type impurities may be injected into the PMOS transistor region of the logic region to form a p-type highly doped impurity region 240b. Accordingly, the floating diffusion region 120 having the DDD or LDD structure and the impurity regions 170, 230, and 240 may be formed.

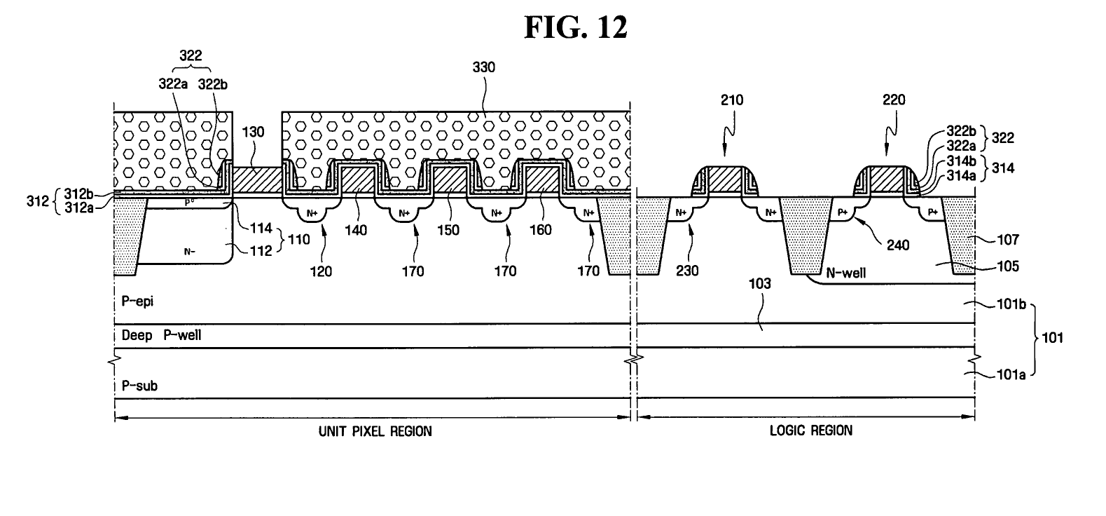

Referring to FIG. 12, a photoresist layer may be formed on the surface (e.g., the entire surface) of the unit pixel region and logic region. The photoresist layer may be patterned to form a mask pattern 330 that simultaneously or concurrently exposes the upper side of the transfer gate 130 in the unit pixel region and the logic region. In this example, the mask pattern 330 may expose an insulating layer (e.g., first insulating layer 310).

An anisotropic etching process may be performed on the first insulating layer 310 using the mask pattern 330 to expose the top surface of the transfer gate 130 and the substrate 101, and the gates 210 and 220 in the logic region.

Because the anisotropic etching process is performed on the first insulating layer 310, multiple spacers may be formed at both sides of the gates 210 and 220 in the logic region. For example, a first spacer 314 and a second spacer 322 may be formed on both sides of the gates 210 and 220 in the logic region. The first spacer 314 may be located below the second spacer 322. The first spacer 314 may be comprised of the first insulating layer 310 and the second spacer 322 may be comprised of the second insulating layer 320.

After performing the anisotropic etching process on the first insulating layer 310, an ashing process may be performed on the first insulating layer 310 to remove the mask pattern 330. An insulating-layer pattern 312, which may cover the gates 140, 150, and 160 and the substrate 101 except for the top surface of the transfer gate 130, may be formed in the unit pixel region. In this example, the insulating-layer pattern 312 may have a single-layered structure including a nitride layer pattern 312b. Alternatively, the insulating-layer pattern may have a multi-layer structure including at least one oxide layer pattern 312a and at least one nitride layer pattern 312b.

As such, the insulating-layer pattern 312b formed in the pixel region may cover the reset element 140, the drive element 150, the selection element 160 and the impurity region 170, and affects to the reset element 140, the drive element 150, the selection element 160, and the impurity region 170 by a silicidation process during the silicidation process may be suppressed and/or prevented.

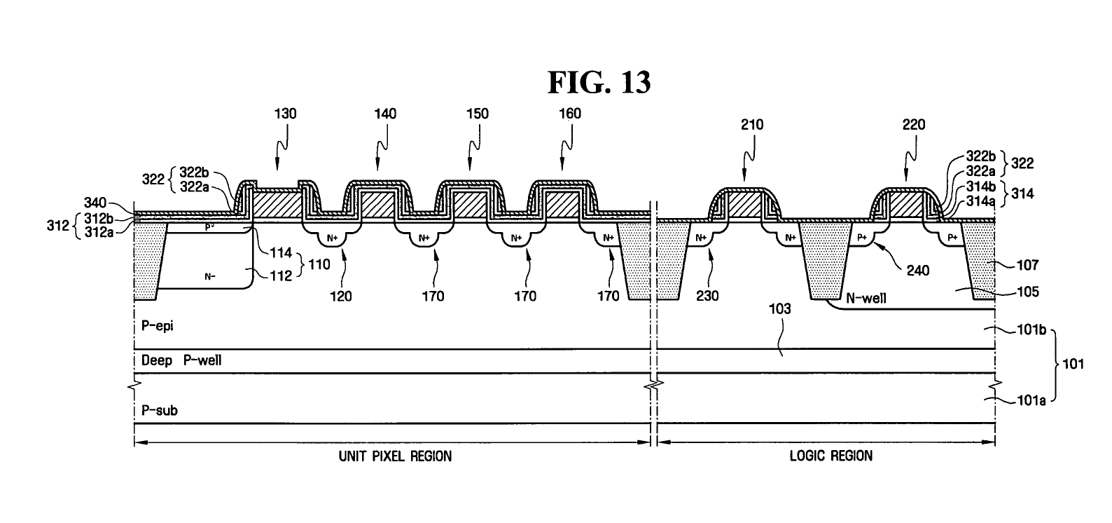

Referring to FIG. 13, a metal layer 340 may be formed to form a silicide layer on a substantial portion of the (e.g., the entire) surface of the unit pixel region and logic region. The metal layer 340 may be formed of, for example, cobalt (Co), titanium (Ti), nickel (Ni), tungsten (W), a combination thereof or the like. After the metal layer 340 is deposited, a thermal treatment may be performed such that a metal material reacts with silicon components of the gates 130, 210, and 220, and the substrate 101 contacting the metal layer 340.

During the silicidation process using the thermal treatment, in the unit pixel region, the insulating-layer pattern 312 may be interposed below the metal layer 340 except for on the top surface of the transfer gate 130. In one example, the insulating-layer pattern 312 may cover the pinned photodiode 110, the floating diffusion region 120, the reset gate 140, the drive gate 150, the selection gate 160 and the impurity region 170, thereby suppressing and/or preventing the silicide layers from being formed on the pinned photodiode 110, the floating diffusion region 120, the reset gate 140, the drive gate 150, the selection gate 160 and the impurity region 170. Further, if the metal layer 340 is formed in the unit pixel region, reduction in sensitivity of unit pixels may be suppressed and/or prevented.

After the silicidation process is performed, the etching process may be performed to remove the metal layer that does not react with the silicon.

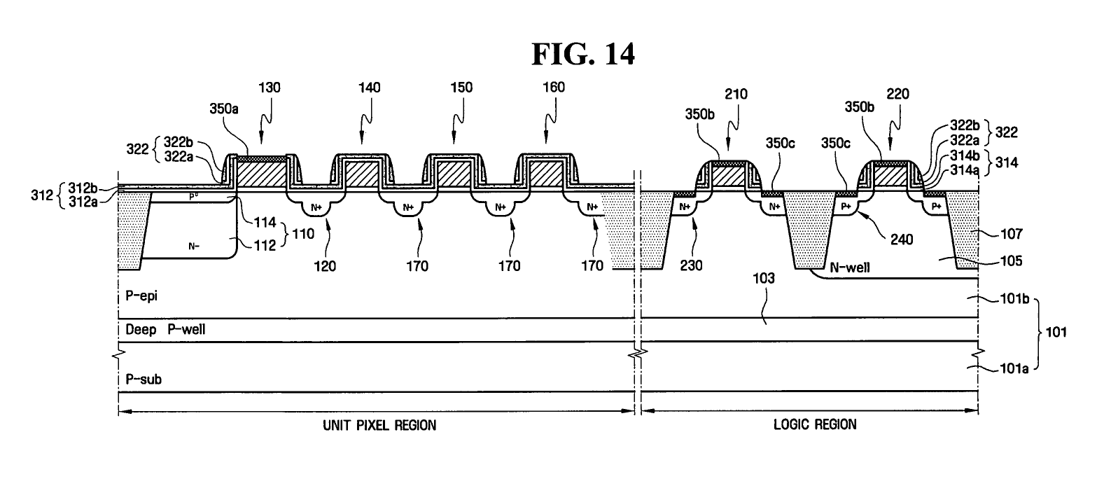

As a result, the silicide layers 350a, 350b and 350c may be formed only on the top surface of the transfer gate 130, the gates 210 and 220 of the logic region, and the top surfaces of the impurity regions 230 and 240, as shown in FIG. 14, for example.

The silicide layers 350a, 350b and 350c formed in the above-described method may reduce contact resistance in the gates 210 and 220 and the impurity regions 230 and 240 of the logic region, thereby improving the operation of the image sensor. Further, because the silicide layer 350a is formed on the top surface of the transfer gate 130 in the unit pixel region, light incident on the pinned photodiode 110 may be suppressed and/or prevented from being incident on the transfer gate 130.

The silicide layers 350a, 350b and 350c located in different regions may be concurrently or simultaneously formed by using the insulting layer pattern 312 that concurrently or simultaneously exposes the top surface of the transfer gate of the pixel region and the logic region. Therefore, processes of manufacturing image sensors may be simplified.

According to example embodiments, the silicide layer may be formed on the top surface of the transfer gate in the unit pixel region, and thus, external light may be suppressed and/or prevented from being incident on the transfer gate. Generation of electron-hole pairs in the regions other than the region where the light-receiving element is formed may also be suppressed, which may reduce the deterioration of image quality of the image sensor.

Further, using an insulting layer pattern that concurrently or simultaneously exposes the top surface of the transfer gate of the unit pixel region and the logic region enables the silicide layers to be formed simultaneously or concurrently on the top surface of the transfer gate and the logic region, which may simplify processes of manufacturing image sensors.

Furthermore, using an insulating-layer pattern that exposes the top surface of the transfer gate in the unit pixel region may reduce affects of the metal material on the unit pixel region during the silicidation process. The sensitivity of the unit pixel region may also be reduced.

Example embodiments should not be construed as being limited to the above-described examples, and the above stated objects as well as other objects, features, and advantages, of the present invention will become clear to those skilled in the art upon review of the preceding description.

The present invention and methods of accomplishing the same may be understood more readily by reference to the above detailed description and the accompanying drawings. The present invention may, however, be embodied in many different forms and should not be construed as being limited to the example embodiments set forth herein. Rather, these embodiments are provided so that this disclosure will be thorough and complete and will fully convey the concept of the invention to those skilled in the art, and the invention will only be defined by the appended claims.

While the present invention has been particularly shown and described with reference to the example embodiments thereof, it will be apparent to those skilled in the art that the scope of the invention is given by the appended claims, rather than the preceding description, and all variations and equivalents which fall within the range of the claims are intended to be embraced therein. Therefore, it should be understood that the above embodiments are not limitative, but illustrative in all aspects.

What is claimed is:

1. A unit pixel formed in a pixel region of a substrate, the unit pixel comprising:
a photodiode for accumulating photocharges;
a floating diffusion region for detecting the photocharges accumulated in the photodiode;
a transfer gate for transferring the photocharges from the photodiode to the floating diffusion region; and
a silicide layer formed on a top surface of only the transfer gate.

2. The unit pixel of claim 1, further including,
a reset element for periodically resetting the floating diffusion region,
a drive element for amplifying the photocharges accumulated in the floating diffusion region, and
a selection element for selecting the unit pixel.

3. An image sensor comprising:
a plurality of unit pixels as claimed in claim 2; and
a logic element corresponding to each unit pixel, each logic element being formed in a logic region of the substrate and processing signals output from the corresponding unit pixel; wherein
a silicide layer is also formed on top surfaces of each corresponding logic element.

4. The image sensor of claim 3, further including,
an insulating-layer pattern formed to cover the photodiode, the floating diffusion region, the reset element, the drive element and the selection element in the pixel region, but expose the top surface of the transfer gate in each unit pixel.

5. The image sensor of claim 4, wherein the silicide layers disposed on the top surfaces of the transfer gates are exposed.

6. The image sensor of claim 4, wherein the insulating-layer pattern includes a single nitride layer or a multi-layered structure including at least one nitride layer and at least one oxide layer.

7. The image sensor of claim 6, wherein the at least one nitride layer and at least one oxide layer are laminated

8. The image sensor of claim 3, wherein each logic element includes a gate electrode and a source/drain region, top surfaces of the gate electrode and the source/drain region having a silicide layer formed thereon.

9. The image sensor of claim 3, wherein the silicide layer formed on the top surface of each transfer gate and logic elements have the same metal components.

10. A method of forming an image sensor comprising:
forming a transfer gate in a pixel region of a substrate;
forming a photodiode in the substrate at a first side of the transfer gate;
forming a floating diffusion region in the substrate at a second side of the transfer gate; and
forming a silicide layer covering a top surface of the transfer gate, but exposing the photodiode and the floating diffusion region.

11. The method of claim 10, further including,
forming a gate of a logic element in a logic region of the substrate,
forming an impurity region in the substrate at each side of the gate of the logic element.

12. The method of claim 11, further including,
forming a silicide layer on a top surface of each gate of the logic element and the impurity region.

13. The method of claim 12, wherein the silicide layers are formed concurrently by,
forming a metal layer on an entire surface of the image sensor, and
performing a thermal treatment on the metal layer.

14. The method of claim 11, the method further including,
forming an insulating-layer pattern on the photodiode and the floating diffusion region.

15. The method of claim 14, wherein the forming of the insulating-layer pattern includes,
forming an insulating layer along the transfer gate and the gate of the logic element,
forming, on the insulating layer, a mask pattern exposing upper sides of the transfer gate and the logic region, and
etching the insulating layer using the mask pattern to form the insulating-layer pattern.

16. The method of claim 15, wherein the insulating layer includes a single nitride layer or a multi-layered structure including at least one nitride layer and at least one oxide layer.

17. The method of claim 16, wherein the at least one nitride layer and the at least one oxide layer are laminated.

18. The method of claim 15, further including,
forming a spacer on the insulating layer at each side of the transfer gate and the gate of the logic element.

19. The method of claim 14, wherein prior to the forming of the insulating-layer pattern, the forming of the insulating-layer pattern further includes,
forming a spacer at each side of the transfer gate and the gate of the logic circuit.

20. The method of claim 11, further including,
forming a reset gate, a drive gate and a selection gate on the substrate in the pixel region, when forming the transfer gate.

21. The method of claim 20, wherein prior to the forming of the silicide layer, the method further includes,
forming an insulating-layer pattern on the pixel region, the insulating-layer pattern exposing the top surface of the transfer gate.

22. The method of claim 21, wherein the forming of the insulating-layer pattern includes,
forming an insulating layer on the substrate along the transfer gate, the reset gate, the drive gate, the selection gate and the gate of the logic element,
forming a mask pattern, which exposes upper sides of the transfer gate and the logic region, on the insulating layer, and
etching the insulating layer using the mask pattern to form the insulating-layer pattern.

23. The method of claim 22, wherein the insulating layer includes a single nitride layer or a multi-layered structure including at least one nitride layer and at least one oxide layer.

24. The method of claim 23, wherein the at least one nitride layer and the at least one oxide layer are laminated.

25. The method of claim 22, further including,
forming a spacer on the insulating layer at each side of the transfer gate, the reset gate, the drive gate, the selection gate and the gate of the logic element.

26. The method of claim 21, wherein prior to forming of the insulating-layer pattern, the method further includes,
forming a spacer at each side of the transfer gate, the reset gate, the drive gate, the selection gate and the gate of the logic element.
